(19) United States
(12) Patent Application Publication
(10) Pub. No.: US 2004/0099944 A1
(43) Pub. Date: May 27, 2004

(54) Semiconductor device

(75) Inventor: Naoto Kimura, Kumamoto-shi (JP)

Correspondence Address: Norman P. Soloway, HAYES SOLOWAY PC, 130 W. Cushing Street, Tucson, AZ, 85701, US

(73) Assignee: NEC Electronics Corporation

(21) Appl. No.: 10/687,309

(22) Filed: Oct. 16, 2003

(30) Foreign Application Priority Data
Nov. 21, 2002 (JP) 338456/2002

(51) Int. Cl. H01L 23/10

(52) U.S. Cl. 257/706

(57) ABSTRACT

A package is formed by mounting a plurality of semiconductor chips 6 and 7 on a substrate 1, arranging a heat spreader 13 on a resin surface opposite to a surface where pads 8 for the semiconductor chips are formed, via a curved intermediate plate 11 made of a metal, and filling with resin 14. The curved intermediate plate 11 is formed so as to easily bend in order to compensate the semiconductor chips 6 and 7 for the height difference relative to the heat spreader 13, and has a plurality of bumps 12 on the surface thereof in order to allow contact with the semiconductor chips by multipoint.

### BACKGROUND OF THE INVENTION

1. Field of the Invention

The present invention relates to a semiconductor device More specifically, it relates to a flip chip ball grid array (FC-BGA) type semiconductor package, which mounts many semiconductor chips differing in size and height and has a heat spreader external thereto.

2. Description of the Prior Art

A conventional FC-BGA type semiconductor package, namely an FC-BGA type semiconductor package where various types of semiconductor chips are mounted on the substrate typically has a structure where a heat spreader is provided on the resin surfaces of the semiconductor chips opposite to the surface on which pads are formed.

However, since the heat spreader is often provided with disregard to size and height of the semiconductor chips, spaces are generated between the heat spreader and the semiconductor chips due to the height difference of the semiconductor chips and the height difference of the junctions between the substrate and the semiconductor chips. Therefore, it is difficult to bond the heat spreader uniformly to the semiconductor chip. In addition, forcing them to be uniform in height causes problems of extra manufacturing time necessary for making all the semiconductor chips to be uniform in thickness and adjusting the heights of the mounted semiconductor chips, and of manufacturing cost increase.

In order to solve such problems, various technologies for heat radiation are employed in the conventional package. Some specific conventional examples are described forthwith while referencing the drawings.

FIG. 1 is a sectional view of a semiconductor package illustrating a first conventional example described in Japanese Patent Application Laid-Open No. Hei 11-68360. As shown in FIG. 1, in such conventional semiconductor package, a semiconductor chip 21 is mounted on a printed board 20 via a flip-chip bonding area 23, and a heat spreader 26 is arranged on the upper side of the semiconductor chip 21 via a flat spring 25. The semiconductor chip 21 is electrically connected to the printed board 20 via solder balls 22.

Nevertheless, since the flat spring 25 has a linear shape, the flat spring 25 and the semiconductor chip 21 are apt to partially contact with each other; in an extreme case, they are contacted in only one place. As a result, the effect of heat radiation decreases. Furthermore, when filling resin into the heat spreader 26, the printed board 20, and the semiconductor chip 21, part of the resin may penetrate into a space between the flat spring 25 and the semiconductor chip 21. As a result, contact between the flat spring 25 and the semiconductor 21 may not be sufficient. When two or more semiconductor chips differing in height are mounted, contact between the flat spring and the semiconductor chips becomes more insufficient.

FIG. 2 is a sectional view of a semiconductor package illustrating a second conventional example described in Japanese Patent Application Laid-Open No. 2000-223631. As shown in FIG. 2, the conventional semiconductor package has a structure where a group of thin metal wires 31 is arranged on the back surface of the semiconductor chip 21 in order to fix the semiconductor chip 21 to the heat spreader 26 via intermediary plates configured with a copper plate 28, a ceramic plate 29, and a copper plate 30. This group of thin metal wires 31 is formed with intricately woven multiple thin metal wires.

With a method utilizing a group of thin metal wires 31 for the semiconductor package, contact between the semiconductor chip 21 and the heat spreader 26 is favorable, however, the thin metal wires come loose and become metal waste during the manufacturing process, possibly causing failure such as an electrical short in other portions. In addition, when filling the semiconductor package with resin, it is difficult to inject the resin uniformly in between each thin metal wire.

FIG. 3 is a sectional view of a semiconductor package illustrating a third conventional example described in Japanese Patent Application Laid-Open No. Hei 7-142647. As shown in FIG. 3, such conventional semiconductor package has a circuit board 34, which is connected to leads 36 on both sides of a package via tubs 37; semiconductor chips 32, which are mounted on the circuit board 34 via bumps 33; a cap 38, which covers the package 35; solders 41A and 41B on the semiconductor chips 32; and high thermal conductivity metal foil 40, which is processed into a flexible shape, and is configured with a heat sink 39 for heat radiation mounted on the cap 38. The high thermal conductivity metal foil 40 is provided for facilitating radiation of the heat generated in the semiconductor chips 32, and convex regions and concave regions of a high thermal conductivity thin metal plate processed into a wave shape are connected to the semiconductor chips 32 and the cap 38 via the solders 41A and 41B, respectively. With such configuration, the heat generated in the semiconductor chips 32 is conducted to the cap 38 and the heat sink 39 via the high thermal conductivity metal foil 40.

In such semiconductor package as with the above-mentioned example of FIG. 1, since the high thermal conductivity metal foil 40 has a flat spring shape, and has no irregularities, contact with the semiconductor chips 32 becomes partial, and the effect of heat radiation may decrease. Especially, when the height of semiconductor chips mounted is different, contact between the semiconductor chips and the high thermal conductivity metal foil becomes more insufficient. Note that in this example, resin is not filled, however, in the case of filling resin, since part of the resin may penetrate into spaces between the high thermal conductivity metal foil 40 and the semiconductor chips 32, contact therebetween may not be sufficient.

With the above-mentioned conventional semiconductor devices, for example, with the first conventional technology, contact becomes partial and the effect of heat radiation easily decreases. When filling resin, part of the resin may penetrate in between the flat spring and the semiconductor chips, and the contact therebetween may be further degraded.

With the second conventional technology, when the thin metal wires become metal waste during the manufacturing process, bonding wires and other wires are electrically shorted, and product defects maybe caused. In addition, when filling resin, it is difficult to uniformly inject resin in between the thin metal wires.

With the third conventional technology, contact becomes partial and the effect of heat radiation easily decreases. In addition, when filling resin, part of the resin may penetrate into the spaces between the high thermal conductivity metal foil and the semiconductor chips, and contact therebetween may be further degraded.

### SUMMARY OF THE INVENTION

The present invention is designed in consideration of the above-mentioned conditions, and the objectives of the present invention are to obtain a sufficiently large and uniform effect of heat radiation, and to provide a semiconductor device which allows prevention of degradation in thermal conductivity even when the height of semiconductor chips mounted is different.

A semiconductor device of the present invention has: a substrate in which an internal wire is formed; at least one semiconductor chip mounted on the substrate; a heat spreader which is used for externally radiating heat from the semiconductor chip; a heat conductive material having flexibility, which is provided between the surface opposite to surfaces of the semiconductor chip near the substrate and the undersurface of the heat spreader in accordance with the height of the space therebetween, and has multiple bumps at least on the semiconductor chip side surface.

The semiconductor device may further comprise resin, which is used for sealing the substrate, the semiconductor chip, the heat conductive material, and the heat spreader.

As the heat conductive material in this semiconductor device, a curved-thin metal intermediate plate with multiple bumps on the upper and the under surface thereof, which is processed into a wave shape having a gradual curvature may be used.

As the heat conductive material in this semiconductor device, a cylindrical metal ring where multiple bumps are formed on the surface thereof may be used.

As the heat conductive material in this semiconductor device, portions of the heat spreader corresponding to the positions of the semiconductor chip may be used as a flat spring, and multiple bumps may be formed on the under-surface thereof.

The above and other objectives and features of the present invention will be apparent from the description based on the accompanied drawings and novel specifications indicated in the claims.

### BRIEF DESCRIPTION OF THE DRAWINGS

In order to facilitate understanding of the drawings utilized in the detailed description of the present invention, respective drawings are briefly described.

FIG. 1 is a sectional view of a semiconductor package illustrating a first conventional example;

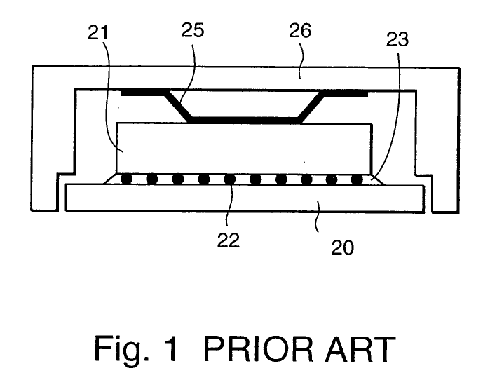

FIG. 2 is a sectional view of a semiconductor package illustrating a second conventional example;

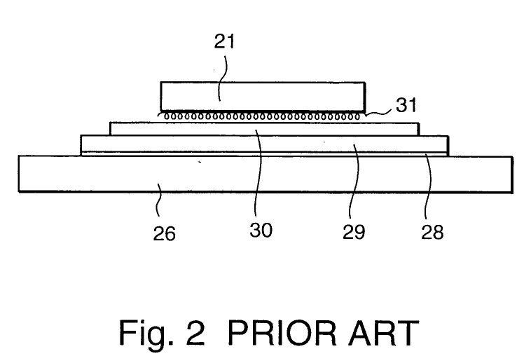

FIG. 3 is a sectional view of a semiconductor package illustrating a third conventional example;

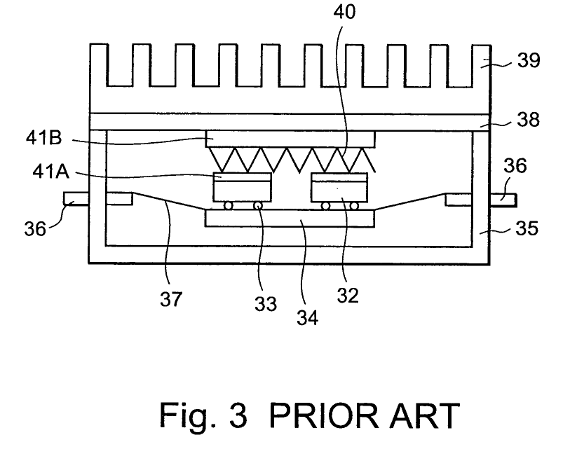

FIG. 4 is a sectional view of a semiconductor package illustrating a first embodiment of a semiconductor device according to the present invention;

FIGS. 5A, 5B, 5C, and 5D are sectional views of a semiconductor package shown in order of process for describing an exemplary embodiment of a manufacturing method for the semiconductor device according to the present invention;

FIG. 6 is a sectional view of a semiconductor package illustrating a second embodiment of a semiconductor device according to the present invention;

FIG. 7 is a sectional view of a semiconductor package illustrating a third embodiment of a semiconductor device according to the present invention; and

FIG. 8 is a sectional view of a semiconductor package illustrating a fourth embodiment of a semiconductor device according to the present invention.

### DETAILED DESCRIPTION OF THE PREFERRED EMBODIMENTS

The preferred embodiments of the present invention are described forthwith while referencing the accompanied drawings. Note that the following descriptions show only some representative embodiments of the present invention, the present invention is not limited to the following descriptions.

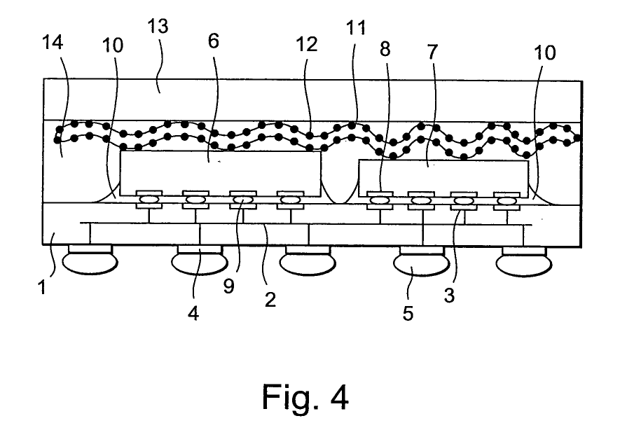

FIG. 4 is a sectional view of a semiconductor package illustrating a first embodiment of a semiconductor device according to the present invention. As shown in FIG. 4, the semiconductor package according to this embodiment includes the following elements: an insulator substrate 1 in which an internal wire 2 is formed, bump lands 3 connected to the internal wire 2 are provided on one surface thereof, and ball bumps 4 are provided on the other surface thereof; a first semiconductor chip 6 and a second semiconductor chip 7, which are mounted on the insulator substrate 1 by connecting pads 8 provided on one principal surface to the respective bump lands 3 in the insulator substrate 1 via gold bumps 9 using the flip-chip method, and have those connected regions sealed with underfill resin 10; a heat spreader 13, which is made of a metal for externally radiating the heat from the first semiconductor chip 6 and the second semiconductor chip 7; a curved intermediate plate 11, which is made of a thin metal material such as copper with high thermal conductivity, has multiple bumps 12, and is arranged between the undersurface of the heat spreader 13 and the surface opposite to the principal surfaces of the first and the second semiconductor chips 6 and 7; and resin 14, which bonds together the insulator substrate 1, the first semiconductor chip 6, the second semiconductor chip 7, the curved intermediate plate 11, and the heat spreader 13. When mounting on a printed board, for example, this semiconductor package is connected to pad regions of the printed board by mounting solder balls 5 on the ball bumps 4 of the substrate 1. Note that solder balls may be used instead of the gold bumps 9.

As the curved intermediate plate 11 which is a heat conductive material of the semiconductor package, thin metal material, such as copper, is used so as to easily bend, and many bumps 12 are formed on the upper- and under-surface thereof. The bumps 12 may actually be formed by deforming or processing the curved intermediate plate 11. In addition, the thickness of the curved intermediate plate 11 falls between approximately 30 μm and 100 μm, and the height of the bumps 12 is approximately 50 μm or less. Since the curved intermediate plate 11 is a thin plate and is processed in to a wave shape having a gradual curvature, the bumps 12 may be easily deformed with a weak pressure so as to fit into the space between the semiconductor chips and the heat spreader.

In addition, as shown in the drawing, the size and height of multiple semiconductor packages 6 and 7 may differ or be the same.

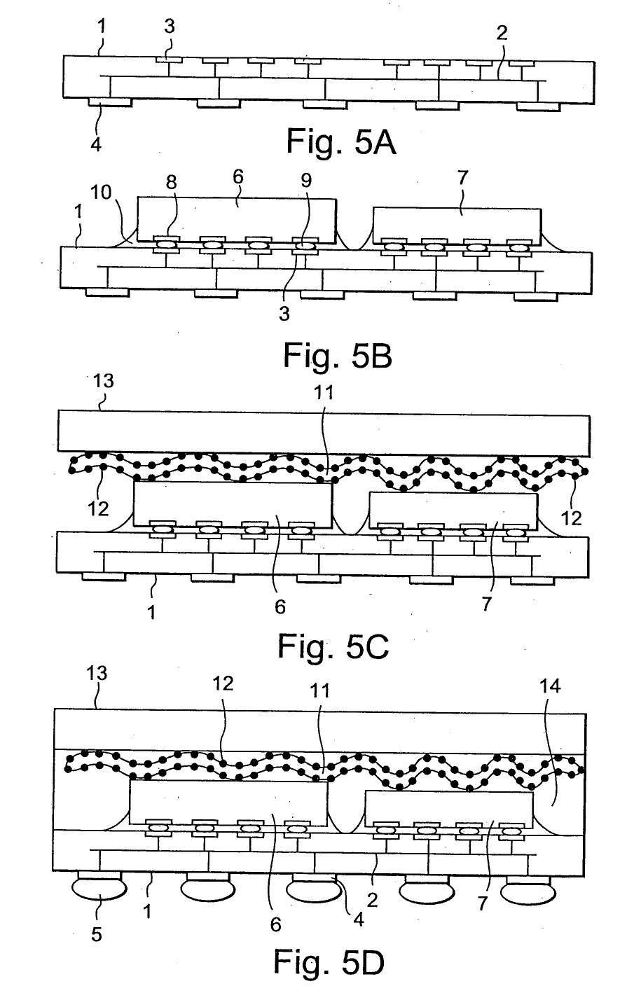

FIGS. 5A through 5D are sectional views of a semiconductor package shown in order of process for describing an exemplary embodiment of a manufacturing method for the semiconductor device according to the present invention. To begin with, as shown in FIG. 5A, the bump lands 3 and ball bumps 4 to be connected to the internal wire 2 are formed on both surfaces of the insulator substrate 1 in which the internal wire 2 is formed.

Next, as shown in FIG. 5B, the semiconductor chips 6 and 7 to which the gold bumps 9 are formed are bonded to the bump lands 3 on the top side of the substrate 1 by applying heat; an ultrasonic vibration, or pressure. The underfill resin 10 is then injected between the substrate 1 and the semiconductor chips 6 and 7 for sealing the periphery of the bonded region in order to protect the bonded region from incoming moisture and dust.

Next, as shown in FIG. 5C, the curved intermediate plate 11 and the heat spreader 13 are mounted on the semiconductor chips 6 and 7. Since the curved intermediate plate 11 compensates the semiconductor chips for the height difference, the substrate 1 and the heat spreader 13 are kept parallel to each other. In this case, the curved intermediate plate 11 can be easily deformed since it is a thin plate with copper as the principle component and the thickness thereof falls between approximately 30 μm and 100 μm, and it can be deformed with a weak pressure since the height of the bumps 12 is approximately 50 μm or less.

Furthermore, as shown in FIG. 5D, the resin 14 is injected into the space between the substrate 1 and the heat spreader 13 while keeping the heat spreader 13 parallel to the substrate 1 on which the semiconductor chips 6 and 7 are mounted. The semiconductor chips 6 and 7, the substrate 1, the curved intermediate plate 11, and the heat spreader 13 are bonded together through the bonding power of the resin 14. Finally, the solder balls 5 are bonded to the ball bumps 4 formed on the principal surface of the substrate 1.

According to the above-mentioned embodiment, by mounting the curved thin intermediate plate 11 with many bumps 12 made of a high thermal conductivity metal between the heat spreader 13 and the plurality of semiconductor chips 6 and 7 with differing height and size, the height difference between the plurality of semiconductor chips 6 and 7 may be compensated, and the heat generated in the plurality of semiconductor chips 6 and 7 may be uniformly conducted to the heat spreader 13 without degrading heat radiation. In addition, since many bumps l2 may be contacted with the semiconductor chips 6 and 7 even when filling in with the resin 14, degradation of the high thermal conductivity due to resin penetrating into the space can be prevented.

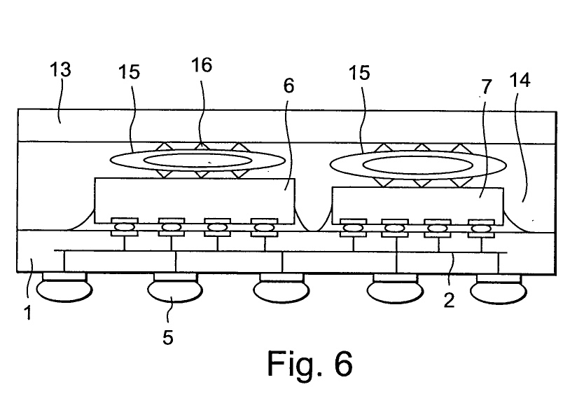

FIG. 6 is a sectional view of a semiconductor package illustrating a second embodiment of a semiconductor device according to the present invention. As shown in FIG. 6, the semiconductor package according to this embodiment has heat conductive material or thin cylindrical metal rings 15 with multiple bumps 16 between the heat spreader 13 and the upper surfaces (back surfaces) of the semiconductor chips 6 and 7. These metal rings 15 are made of a high thermal conductivity metal such as copper, and may be deformed so as to fit into the space between the heat spreader 13 and the semiconductor chips 6 and 7. Note that other materials are the same as those in the above-mentioned first embodiment of FIG. 4.

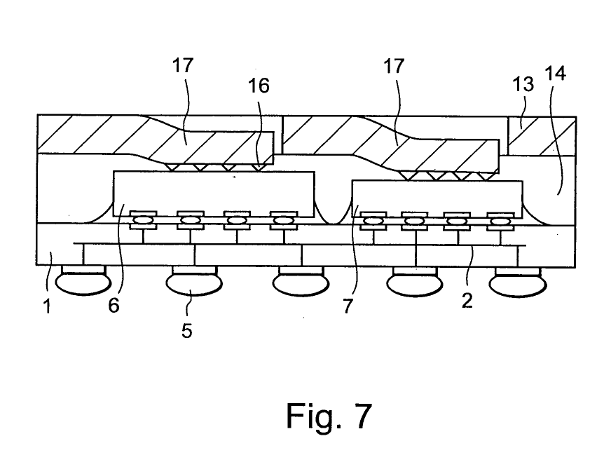

FIG. 7 is a sectional view of a semiconductor package illustrating a third embodiment of a semiconductor device according to the present invention. As shown in FIG. 7, in the semiconductor package according to this embodiment, portions of the heat spreader 13 corresponding to the positions of the semiconductor chips 6 and 7 are cut out, and flat springs 17 are formed instead. In addition, multiple bumps 16 are provided on the under-surface of the flat springs 17 and are pressed against the back surface of the semiconductor chips so as to also function as the heat conductive material. The height difference between the semiconductor chips 6 and 7 relative to the heat spreader 13 is compensated by varying the stiffness of the flat springs 17. In addition, other materials are the same as those in FIG. 6 described above.

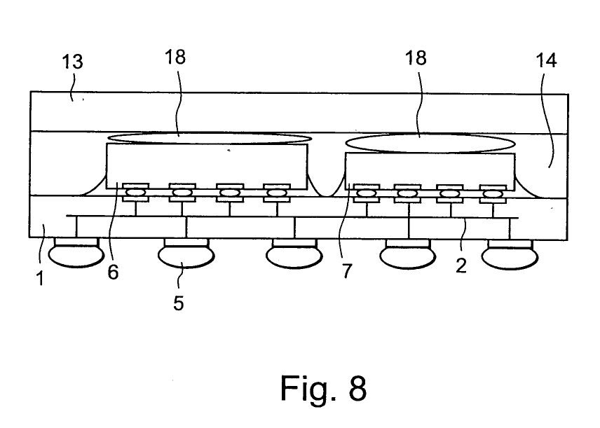

FIG. 8 is a sectional view of a semiconductor package illustrating a fourth embodiment of a semiconductor device according to the present invention. As shown in FIG. 8, in the semiconductor package according to this embodiment, a high thermal conductivity adhesive 18 is used instead of the metal rings and flat springs of the above-mentioned second or third embodiment. By coating a silver paste, for example, as the high thermal conductivity adhesive 18 to vary the thickness of the high thermal conductivity adhesive 18, the height difference between the semiconductor chips-6 and 7 relative to the heat spreader 13 is compensated so that the heat spreader 13 can be suitably positioned. In addition, other materials are the same as those in FIG. 6 described above.

Furthermore, manufacturing methods of the semiconductor device in these embodiments may be implemented as with the above-mentioned procedure of FIG. 5.

As described above, since the height difference between the plurality of semiconductor chips may be compensated by mounting the heat conductive materials with bumps made of a high thermal conductivity metal between the semiconductor chips and the heat spreader, or by filling with a high thermal conductivity adhesive therebetween, a semiconductor device according to the present invention have the effects that heat can be uniformly conducted to the heat spreader without degrading the heat radiation generated from both semiconductor chips and that degradation of the thermal conductivity due to resin penetrating into the space can be prevented even when filling resin.

What is claimed is:

1. A semiconductor device comprising:
a substrate in which an internal wire is formed;
at least one semiconductor chip mounted on the substrate;
a heat spreader which is used for externally radiating heat from the semiconductor chip; and
a heat conductive material having flexibility, which is provided between the surface opposite to surfaces of the semiconductor chip near the substrate and the undersurface of the heat spreader in accordance with the height of the space therebetween, and has a plurality of bumps at least on the semiconductor chip side surface.

2. The semiconductor device according to claim 1, further comprising resin, which is used for sealing the substrate, the semiconductor chip, the heat conductive material, and the heat spreader.

3. The semiconductor device according to claim 1, wherein the heat conductive material is a curved thin metal intermediate plate with a plurality of bumps on the upper- and the under-surface thereof, which is processed into a wave shape having a gradual curvature.

4. The semiconductor device according to claim 3, wherein the plurality of bumps of the curved intermediate plate is formed by deforming or processing the curved intermediate plate.

5. The semiconductor device according to claim 3, wherein the curved intermediate plate is made of copper as the principle component.

6. The semiconductor device according to claim 1, wherein the heat conductive material is a cylindrical metal ring with a plurality of bumps provided on a surface thereof.

7. The semiconductor device according to claim 1, wherein the heat conductive material uses a portion of the heat-spreader corresponding to a position of the semiconductor chip as a flat spring and a plurality of bumps are formed on the undersurface thereof.

8. A semiconductor device comprising:
a substrate in which an internal wire is formed;
a plurality of semiconductor chips mounted on the substrate;
a heat spreader which is used for externally radiating heat from the plurality of semiconductor chips; and
a heat conductive material having flexibility, which is provided between the surfaces opposite to surfaces of the plurality of semiconductor chips near the substrate and the undersurface of the heat spreader in accordance with the height of the space therebetween, and has a plurality of bumps at least on the semiconductor chip side surface.

9. The semiconductor device according to claim 8, further comprising resin, which is used for sealing the substrate, the plurality of semiconductor chips, the heat conductive material, and the heat spreader.

10. The semiconductor device according to claim 8, wherein the heat conductive material is a curved thin metal intermediate plate with a plurality of bumps on the upper- and the under-surface thereof, which is processed into a wave shape having a gradual curvature.

11. The semiconductor device according to claim 10, wherein the plurality of bumps of the curved intermediate plate is formed by deforming or processing the curved intermediate plate.

12. The semiconductor device according to claim 10, wherein the curved intermediate plate is made of copper as the principle component.

13. The semiconductor device according to claim 8, wherein the heat conductive material is a cylindrical metal ring with a plurality of bumps provided on a surface thereof.

14. The semiconductor device according to claim 8, wherein the heat conductive material uses a portion of the heat spreader corresponding to a position of the plurality of semiconductor chips as a flat spring and a plurality of bumps are formed on the undersurface thereof.
